(19) United States
(12) Patent Application Publication
(10) Pub. No.: US 2026/0056460 A1
(43) Pub. Date: Feb. 26, 2026

(54) APODIZATION MEASUREMENT OPTICS AND MEASUREMENT METHOD FOR EUV RETICLE INSPECTION TOOL

(71) Applicant: KLA Corporation, Milpitas, CA (US)

(72) Inventors: Yashuhiro Hidaka, Milpitas, CA (US); Junwon Lee, San Jose, CA (US)

(21) Appl. No.: 19/265,602

(22) Filed: Jul. 10, 2025

Related U.S. Application Data
(60) Provisional application No. 63/686,174, filed on Aug. 23, 2024.

(51) Int. Cl. G03F 1/84; G03F 9/00

(52) U.S. Cl. CPC G03F 1/84; G03F 9/7019

(57) ABSTRACT

An inspection system may be an EUV reticle inspection tool. The inspection system may include objective optics and imaging optics. The imaging optics may include pupil-relay optics. A first pupil-relay mirror of the pupil-relay optics may be extended into and retracted from the imaging path to enable imaging field images and pupil images on a detector. The pupil images may be used for measuring the intensity profile in pupil. Configurations of the pupil-relay optics may include the first pupil-relay mirror extending between a second and third objective mirrors of the objective optics or extending between fourth objective mirror of the objective optics and the detector.

### CROSS-REFERENCE

The present application claims the benefit under 35 U.S.C. § 119 of U.S. Provisional application 63/686,174, filed on Aug. 23, 2024, titled “Apodization Measurement Optics and Measurement Method for EUV Reticle Inspection Tool”, which is incorporated herein by reference in the entirety.

### TECHNICAL FIELD

The present disclosure generally relates to mask projection systems and, more particularly, to optical aspects of extreme ultraviolet (EUV) systems.

### BACKGROUND

Some inspection systems use deep ultraviolet (DUV) wavelengths. DUV inspection systems may use lenses and beamsplitter to determine a pupil intensity profile of the collected light. The DUV inspections systems may use the beamsplitter to produce a reference beam to measure stability and uniformity of the DUV light over time and at different locations within the beam.

As the node size of semiconductor process decreases, DUV inspection systems may not be sufficient to resolve the features and defects the of the smaller node sizes. Apparatus that utilize DUV light are clearly limited when applied to inspect extreme ultraviolet (EUV) masks or other samples. The conventional apparatus are typically “non-actinic” in that they result in an image of the mask that does not represent what will be realized using EUV light during lithography. Rather, the resultant image of the mask lacks both resolution and contrast, such that the image is not very useful for pattern inspection and defect detection. Accordingly, the size and type of defects that can be detected and reviewed are limited. To resolve features and defects of the smaller node sizes, EUV inspection systems may be used.

EUV inspection systems present problems that are not found in the DUV inspection systems. The inspection of EUV masks using actinic radiation (e.g., 13.5 nm) poses challenges and departures from mask inspection technology for earlier inspected nodes. Beamsplitter elements are difficult to implement for EUV wavelengths, as the beamsplitter may strongly absorb the EUV wavelengths. The use of beamsplitters in reflective imaging systems used in conjunction with reflective objects (such as EUV mask inspection using EUV light) can simplify optical design and layout, by allowing interpenetration or overlap of illumination and imaging pupils in angle space. However, the EUV inspection systems may not use the beamsplitter for detecting the pupil intensity profile without significant losses. Current EUV beam splitter technology have low reflection and transmission coefficients (25-35%). Inspection systems with beamsplitters must increase source brightness greatly to compensate for the loss of light reaching the detector. Inspection optics without the beamsplitter is thus strongly preferred. Therefore, it would be advantageous to provide a device, system, and method that cures the shortcomings described above.

### SUMMARY

Imaging optics are described, in accordance with one or more embodiments of the present disclosure. The imaging optics may include: an aperture stop, wherein the aperture stop defines a pupil plane of collected light in an imaging path, wherein the pupil plane is a reciprocal plane to a field plane on a sample, wherein the aperture stop is arranged in the imaging path between the sample and objective optics; the objective optics, wherein the objective optics include a first objective mirror, a second objective mirror, a third objective mirror, and a fourth objective mirror; and pupil-relay optics, wherein the pupil-relay optics include at least a first pupil-relay mirror, wherein the imaging optics are configurable between a field-imaging mode and a pupil-imaging mode, wherein the imaging optics are configured in the pupil-imaging mode by extending the first pupil-relay mirror into the imaging path and are configured in the field-imaging mode by retracting the first pupil-relay mirror from the imaging path, wherein the objective optics are configured to image field images on a detector in the field-imaging mode, wherein the field images are a conjugate of the field plane, wherein at least the first objective mirror and the second objective mirror of the objective optics and the pupil-relay optics are configured to image pupil images on the detector in the pupil-imaging mode, wherein the pupil images are a conjugate of the pupil plane.

An inspection system is described, in accordance with one or more embodiments of the present disclosure. The inspection system may include: imaging optics including: an aperture stop, wherein the aperture stop defines a pupil plane of collected light in an imaging path, wherein the pupil plane is a reciprocal plane to a field plane on a sample, wherein the aperture stop is arranged in the imaging path between the sample and objective optics; the objective optics, wherein the objective optics include a first objective mirror, a second objective mirror, a third objective mirror, and a fourth objective mirror; and pupil-relay optics, wherein the pupil-relay optics include at least a first pupil-relay mirror, wherein the imaging optics are configurable between a field-imaging mode and a pupil-imaging mode, wherein the imaging optics are configured in the pupil-imaging mode by extending the first pupil-relay mirror into the imaging path and are configured in the field-imaging mode by retracting the first pupil-relay mirror from the imaging path, wherein the objective optics are configured to image field images on a detector in the field-imaging mode, wherein the field images are a conjugate of the field plane, wherein at least the first objective mirror and the second objective mirror of the objective optics and the pupil-relay optics are configured to image pupil images on the detector in the pupil-imaging mode, wherein the pupil images are a conjugate of the pupil plane; an illumination source; illumination optics; a stage, wherein the stage is configured to support the sample; the detector; and a controller, wherein the controller is configured to receive the field images and the pupil images from the detector.

A method is described, in accordance with one or more embodiments of the present disclosure. The method may include: extending a first pupil-relay mirror of pupil-relay optics of imaging optics into an imaging path to configure the imaging optics in a pupil-imaging mode; detecting pupil images while the imaging optics are configured in the pupil-imaging mode; compensating for a relay-reflectivity profile by moving a second objective mirror of objective optics of the imaging optics relative to a collected light; determining a pupil-intensity profile of the collected light from the pupil images after compensating for the relay-reflectivity profile; generating a simulated image based on the pupil-intensity profile; retracting the first pupil-relay mirror from the imaging path to configure the imaging optics in a field-imaging mode; detecting field images while the imaging optics are configured in the field-imaging mode; and comparing the simulated image and the field images.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the description and drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1A illustrates a conceptual view of an inspection system with imaging optics, in accordance with one or more embodiments of the present disclosure.

FIG. 1B illustrates a simplified block diagram of the imaging optics including objective optics, pupil-relay optics, and an aperture stop, in accordance with one or more embodiments of the present disclosure.

FIG. 2A illustrates a simplified optical ray diagram of the imaging optics configured in a field-imaging mode, in accordance with one or more embodiments of the present disclosure.

FIG. 2B illustrates a schematic of the imaging optics configured in the field-imaging mode, in accordance with one or more embodiments of the present disclosure.

FIG. 2C illustrates a simplified optical ray diagram of the imaging optics configured in a pupil-imaging mode, in accordance with one or more embodiments of the present disclosure.

FIG. 2D illustrates a schematic of the imaging optics configured in the pupil-imaging mode, in accordance with one or more embodiments of the present disclosure.

FIG. 3A illustrates a schematic of the imaging optics configured in the field-imaging mode, in accordance with one or more embodiments of the present disclosure.

FIG. 3B illustrates a schematic of the imaging optics configured in the pupil-imaging mode, in accordance with one or more embodiments of the present disclosure.

FIG. 4A illustrates a schematic of the imaging optics configured in the field-imaging mode, in accordance with one or more embodiments of the present disclosure.

FIG. 4B illustrates a schematic of the imaging optics configured in the pupil-imaging mode, in accordance with one or more embodiments of the present disclosure.

FIG. 5 illustrates a beam footprint diagram, in accordance with one or more embodiments of the present disclosure.

FIG. 6 illustrates a flow diagram of a method, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to apodization measurement optics and measurement method for an EUV reticle inspection tool. An inspection system may be an EUV reticle inspection tool. The inspection system may include objective optics and imaging optics. The imaging optics may include pupil-relay optics. A first pupil-relay mirror of the pupil-relay optics may be extended into and retracted from the imaging path to enable imaging field images and pupil images on a detector. The pupil images may be used for measuring the intensity profile in pupil. Configurations of the pupil-relay optics may include the first pupil-relay mirror extending between a second and third objective mirrors of the objective optics or extending between fourth objective mirror of the objective optics and the detector.

U.S. Pat. No. 8,553,217B2, titled “EUV high throughput inspection system for defect detection on patterned EUV masks, mask blanks, and wafers”; U.S. Pat. No. 8,842,272B2, titled “Apparatus for EUV imaging and methods of using same”; U.S. Pat. No. 8,916,831B2, titled “EUV actinic reticle inspection system using imaging sensor with thin film spectral purity filter coating”; U.S. Pat. No. 9,151,718B2, titled “Illumination system with time multiplexed sources for reticle inspection”; U.S. Pat. No. 9,151,881B2, titled “Phase grating for mask inspection system”; U.S. Pat. No. 9,348,214B2, titled “Spectral purity filter and light monitor for an EUV reticle inspection system”; U.S. Pat. No. 9,448,343B2, titled “Segmented mirror apparatus for imaging and method of using the same”; U.S. Pat. No. 9,544,984B2, titled “System and method for generation of extreme ultraviolet light”; U.S. Pat. No. 9,915,625B2, titled “Optical die to database inspection”; U.S. Pat. No. 10,012,599B2, titled “Optical die to database inspection”; U.S. Pat. No. 10,309,907B2, titled “All reflective wafer defect inspection and review systems and methods”; U.S. Pat. No. 10,380,728B2, titled “Model-based metrology using images”; U.S. Pat. No. 10,527,830B2, titled “Off-axis reflective afocal optical relay”; U.S. Pat. No. 10,893,599B2, titled “Laser produced plasma light source having a target material coated on a cylindrically-symmetric element”; U.S. Pat. No. 10,921,262B2, titled “Correlating SEM and optical images for wafer noise nuisance identification”; U.S. Pat. No. 11,112,691B2, titled “Inspection system with non-circular pupil”; U.S. Pat. No. 11,293,880B2, titled “Method and apparatus for beam stabilization and reference correction for EUV inspection”; U.S. Pat. No. 11,499,924B2, titled “Determining one or more characteristics of light in an optical system”; U.S. Pat. No. 11,733,605B2, titled “EUV in-situ linearity calibration for TDI image sensors using test photomasks”; U.S. Patent Publication Number US20130250428A1, titled “Magnifying imaging optical unit and metrology system comprising such an imaging optical unit”; U.S. Patent Publication Number US20150192459A1, titled “Extreme ultra-violet (euv) inspection systems”; are each incorporated herein by reference in the entirety.

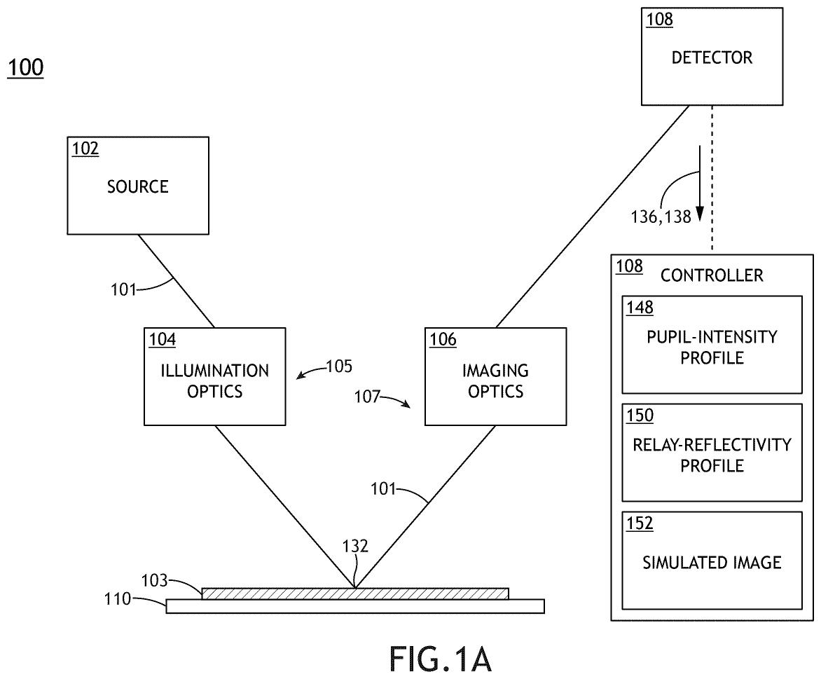

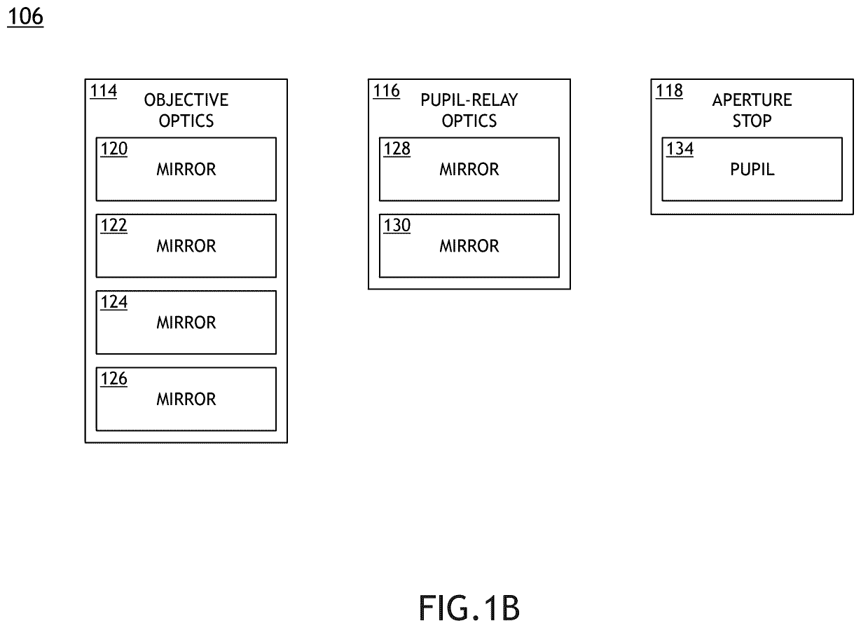

FIG. 1A-1B illustrate an inspection system 100, in accordance with one or more embodiments of the present disclosure. The inspection system may be an EUV reticle inspection tool, an EUV inspection system, a EUV mask projection system, or the like. The inspection system 100 may include illumination 101, an illumination source 102, a sample 103, illumination optics 104, an illumination path 105, imaging optics 106, an imaging path 107, a detector 108, a stage 110, a controller 112, objective optics 114, pupil-relay optics 116, an aperture stop 118, a first objective mirror 120, a second objective mirror 122, a third objective mirror 124, a fourth objective mirror 126, a first pupil-relay mirror 128, and/or a second pupil-relay mirror 130.

The inspection system 100 may be configured to inspect the sample 103. The inspection system 100 may be configured to inspect the sample 103 by illuminating the sample 103 with illumination 101, collect collected light 109 from the sample 103, and detecting field images 136 and/or the pupil images 138 based on the collected light 109. The collected light 109 may include a field plane 132, a pupil plane 134, the field images 136, the pupil images 138, intermediate field conjugates 140, intermediate pupil conjugates 142, chief rays 144, and/or marginal rays 146.

The illumination 101 and/or the collected light 109 may be vacuum ultraviolet (VUV) light and/or soft X-ray light. The VUV light and/or the soft X-ray light may be operated in a vacuum to prevent the atmosphere from absorbing the light. The VUV light may have a wavelength of between 10 nm and 180 nm. The soft X-ray light may have a wavelength of between 0.1 and 10 nm. The VUV light may be far ultraviolet (FUV) light and/or extreme ultraviolet (EUV) light. The FUV light may have a wavelength of between 121 and 180 nm. The EUV light may have a wavelength of between 10 nm and 121 nm. For example, the EUV light may have a wavelength between 5 nm and 30 nm. For instance, the EUV light may have a wavelength between 5 and 15 nm. In embodiments, the illumination 101 may be in-band EUV light having a wavelength of 13.5 nm. For example, the in-band EUV light may have a wavelength of 13.5 nm with 2% bandwidth. Although the illumination 101 and/or the collected light 109 is described as the in-band EUV light, EUV light and/or VUV light at other wavelength ranges may also be used. The illumination 101 and/or the collected light 109 may be continuous, pulsed, modulated, or the like. For example, the illumination 101 and/or the collected light 109 may be pulsed.

The illumination source 102 may be configured to emit the illumination 101. The illumination source 102 may include one or more components (not depicted) by which the illumination source 102 is configured to emit the illumination 101. The illumination source 102 may include laser-produced plasma (LPP) sources, discharge-produced plasma (DPP) sources, and the like. For example, the illumination source 102 may include a laser-produced plasma source. The illumination source 102 may be a continuous, pulsed, or modulated illumination source. For example, the illumination source 102 may be a pulsed illumination source. The illumination source 102 may also include multiple emitters which are multiplexed together. For example, the emitters may be multiplexed together via a multiplexing mirror system. Multiplexing the emitters together may be beneficial to increase a power and/or brightness of the illumination 101.

The inspection system 100 may direct the illumination 101 to the sample 103. For example, the inspection system 100 may be configured to direct the illumination 101 to the sample 103 along the illumination path 105. The illumination path 105 may be an optical path for providing the illumination 101 to the sample 103 being inspected. The illumination path 105 may include the illumination optics 104 which direct the illumination 101 to the sample 103. The illumination optics 104 may include one or more optical components (not depicted). The optical components may be optical mirrors (e.g., due to the wavelength of the illumination 101). The illumination optics 104 may reflect the illumination 101 such that the illumination 101 illuminates the sample 103. The illumination optics 104 may include a series of condensing mirrors configured to condense the illumination 101 into a narrow beam directed to the sample 103. The illumination optics 104 may also include a multiplexing mirror to multiplex the illumination 101 from one or more of the illumination sources 102. The optical components may also process and/or shape the illumination 101 prior to directing onto the sample 103. For example, the illumination optics 104 may include collector optics, homogenizers, spectral purity filters, relays, condensers, and the like. The collector optics may collect the illumination 101 from the illumination source 102 and direct the illumination 101 to the sample 103. The homogenizer may change the illumination 101 from a gaussian beam to a flat-top beam. The flat-top beam may also be referred to as a top-hat beam. The spectral purity filter may filter wavelengths (e.g., drive laser wavelengths of the illumination source 102) from the illumination 101. The relays may relay the illumination 101 between any of the various optical components of the illumination optics 104. The condenser may condense the illumination 101 into a converging beam on the sample 103. The illumination path 105 may also include an additional aperture stop (not depicted), which may be referred to as an illumination-aperture stop.

The sample 103 may include a mask blank, a photomask, a wafer, a die, or the like. The photomask may also be referred to as a reticle. For example, the sample 103 may be a photomask used in extreme ultraviolet (EUV) lithography.

The stage 110 may support the sample 103. The stage 110 may be an actuatable stage. The illumination 101 and/or the collected light 109 may be scanned in a scanning direction over the sample 103. The stage 110 may scan the illumination 101 and the collected light 109 in a scanning direction over the sample 103. The sample 103 may be scanned under the illumination 101 and/or the collected light 109 by actuating the stage 110. The stage 110 may include any device suitable for positioning and/or scanning the sample 103 within the inspection system 100. For example, the stage 110 may include any combination of linear translation stages, rotational stages, tip/tilt stages, or the like. For example, the stage 110 may include, but is not limited to, one or more translational stages suitable for translating the sample 103 along one or more linear directions (e.g., x-direction, y-direction, and/or z-direction). By way of another example, the stage 110 may include, but is not limited to, one or more rotational stages suitable for rotating the sample 103 along a rotational direction. By way of another example, the stage 110 may include, but is not limited to, a rotational stage and a translational stage suitable for translating the sample 103 along a linear direction and/or rotating the sample 103 along a rotational direction.

The illumination 101 may reflect from the sample 103 as collected light 109. The collected light 109 may reflect via specular reflection, scattering, diffusion, or the like. The illumination path 105 and the imaging path 107 may be spatially separated. The illumination 101 and the collected light 109 may be off-axis when being directed to and reflected from, respectively, the sample 103. The collected light 109 may reflect from the sample 103 off-axis to the illumination 101. The collected light 109 may be patterned light. For example, the collected light 109 may be patterned according to the mask, the wafer, and/or the die of the sample 103. The pattern may also indicate defects associated with the sample 103. The illumination source 102 may also illuminate the sample 103 via critical illumination. The collected light 109 may be the EUV light (e.g., the in-band EUV light).

The imaging path 107 may be the optical path for collected light 109 from the sample 103 being inspected to the detector 108. The imaging optics 106 may be configured to direct the collected light 109 from the sample 103 to the detector 108 along the imaging path 107. The imaging path 107 may include the imaging optics 106 which direct the collected light 109 to the detector 108. The imaging optics 106 may be between the field plane 132 and the detector 108. The imaging optics 106 may include the objective optics 114, the pupil-relay optics 116 and/or the aperture stop 118. The objective optics 114 may include the first objective mirror 120, the second objective mirror 122, the third objective mirror 124, and/or the fourth objective mirror 126. The pupil-relay optics 116 may include the first pupil-relay mirror 128 and/or the second pupil-relay mirror 130.

The aperture stop 118 may be arranged in the imaging path 107 between the sample 103 and the objective optics 114 and/or the pupil-relay optics 116. For example, the aperture stop 118 may be arranged in the imaging path 107 between the sample 103 and the first objective mirror 120. The aperture stop 118 may define a pupil plane 134 of the collected light 109. The aperture stop 118 may also be referred to as an imaging-aperture stop.

The imaging optics 106 may output a projection of the collected light 109 onto the detector 108. The imaging optics 106 may collect the collected light 109 and form images at the detector 108. For example, the imaging optics 106 may be configured to image the field images 136 and/or the pupil images 138 on the detector 108. The field images 136 may be a conjugate of the field plane 132. For example, the objective optics 114 may image the field images 136 on the detector 108. By way of another example, the objective optics 114 and the pupil-relay optics 116 may image the pupil images 138 on the detector 108.

The field plane 132 may also be referred to as an object plane, a reticle plane, a mask plane, or the like. The field plane 132 may be the reflection of the illumination 101 on the sample 103. The field plane 132 may be represented by one or more field points. The collected light 109 reflected, diffracted, or scattered from different locations on the sample 103 may be detected in different locations in the field plane 132, regardless of the collection angle.

The pupil plane 134 may represent a range of angles within which the collected light 109 is collected from the sample 103 (e.g., an imaging pupil distribution). The pupil plane 134 may be a reciprocal plane to the field plane 132 on the sample 103. The pupil plane 134 may correspond to a diffraction pattern and/or Fourier transform of the field plane 132. For example, the collected light 109 emanating from the field plane 132 at a particular angle, regardless of the location in the field plane 132, may be focused to a particular point in the pupil plane 134. The collected light 109 reflected, diffracted, or scattered at different angles from the sample 103 may be detected in different locations in the pupil plane 134, regardless of the location of the interaction with the collected light 109 on the sample 103.

The field images 136 and/or the intermediate field conjugates 140 may be conjugates to the field plane 132. For example, the collected light 109 emanating from a particular point of the field plane 132 at any angle may be imaged to a corresponding to a particular point in the field images 136 and/or the intermediate field conjugates 140. The imaging optics 106 may include one or more of the intermediate field conjugates 140 between the field plane 132 and the field images 136. The field images 136 may also be referred to as a final-field conjugate. The field images 136 may be a final conjugate plane of the field plane 132.

The pupil images 138 and/or the intermediate pupil conjugates 142 may be conjugates to the pupil plane 134. The imaging optics 106 may include one or more of the intermediate pupil conjugates 142 between the pupil plane 134 and the pupil images 138. The pupil images 138 may also be referred to as final-pupil plane conjugates. The pupil images 138 may be a final conjugate plane of the pupil plane 134. The pupil images 138 and/or the intermediate pupil conjugates 142 may also be reciprocal to the field plane 132 by being conjugates to the pupil plane 134. For example, the collected light 109 from a single point in the field plane 132 may be incident on all points of the pupil images 138 and/or the intermediate pupil conjugates 142.

The chief rays 144 may be rays of the collected light 109 passing on the optical axis in the pupil plane of the aperture stop 118. The chief rays 144 may originate from the sample 103 off-axis to the optical axis. The chief rays 144 may intersect the optical axis at the pupil images 138 and/or the intermediate pupil conjugates 142.

The marginal rays 146 may be the collected light 109 which originates on the optical axis and passes through the edge of the aperture stop 118. The marginal rays 146 may cross the optical axis on the detector 108 in the field-imaging mode 106a, because the field images 136 are a conjugate plane with the field plane 132. The marginal rays 146 may intersect the optical axis at the field images 136 and/or the intermediate field conjugates 140.

The imaging optics 106 may be configurable between a field-imaging mode 106a and a pupil-imaging mode 106b. The field-imaging mode 106a may also be referred to as an inspection mode. The pupil-imaging mode 106b may also be referred to as a pupil-intensity-distribution measurement mode. The imaging path 107 may follow a different path within the imaging optics 106 in the field-imaging mode 106a and the pupil-imaging mode 106b. The imaging optics 106 may direct the collected light 109 to the detector 108 in both the field-imaging mode 106a and the pupil-imaging mode 106b. However, the images generated by collected light 109 on the detector 108 may be different between the field-imaging mode 106a and the pupil-imaging mode 106b. For example, the imaging optics 106 may image the field images 136 on the detector 108 in the field-imaging mode 106a and image the pupil images 138 on the detector 108 in the pupil-imaging mode 106b. In the field-imaging mode 106a, the marginal rays 146 may be focused on the detector 108 (e.g., on the optical axis). In the pupil-imaging mode 106b, the chief rays 144 may be focused on the detector 108 (e.g., on the optical axis).

The imaging optics 106 may include the field-imaging mode 106a. The imaging optics 106 may image the field images 136 on the detector 108 in the field-imaging mode 106a. The objective optics 114 of the imaging optics 106 may image the field images 136 on the detector 108 in the field-imaging mode 106a. The objective optics 114 may image the field images 136 on the detector 108 by reflecting the collected light 109 from the field plane 132 to the detector 108 using the first objective mirror 120, the second objective mirror 122, the third objective mirror 124, and the fourth objective mirror 126.

The imaging optics 106 may also include the pupil-imaging mode 106b. The imaging optics 106 may image the pupil images 138 on the detector 108 in the pupil-imaging mode 106b. At least the first objective mirror 120 and the second objective mirror 122 of the objective optics 114 and the pupil-relay optics 116 may image the pupil images 138 on the detector 108 in the pupil-imaging mode 106b. For example, the first objective mirror 120 and the second objective mirror 122 of the objective optics 114 together with the pupil-relay optics 116 may image the pupil images 138 on the detector 108, without reflecting from the third objective mirror 124 and/or the fourth objective mirror 126. By way of another example, the first objective mirror 120, the second objective mirror 122, and the fourth objective mirror 126 of the objective optics 114 together with the pupil-relay optics 116 may image the pupil images 138 on the detector 108, without reflecting from the third objective mirror 124. By way of another example, the first objective mirror 120, the second objective mirror 122, the third objective mirror 124, and the fourth objective mirror 126 of the objective optics 114 together with the pupil-relay optics 116 may image the pupil images 138 on the detector 108.

The imaging optics 106, the objective optics 114 and/or the pupil-relay optics 116 may include optical mirrors (e.g., reflective optics). For example, the imaging optics 106, the objective optics 114 and/or the pupil-relay optics 116 may be catoptric with only reflective elements and no refractive elements, due to the wavelength of the collected light 109. It is further contemplated that the imaging optics 106, the objective optics 114 and/or the pupil-relay optics 116 may be catadioptric with reflective elements and refractive elements, and at expense of a brightness of the collected light 109. However, the objective optics 114 and/or the pupil-relay optics 116 being catoptric may be beneficial to reduce the absorbance of the collected light 109.

The imaging optics 106, the objective optics 114, and/or the pupil-relay optics 116 may be characterized both by the number of the optical mirrors and the arrangements according to the sign of the optical powers (also referred to as convergence powers). For example, the optical mirrors may be flat mirrors, concave mirrors, and/or convex mirrors. The flat mirrors may have zero optical power (e.g., 0) and may be referred to as plano mirrors. The concave mirrors may have a negative optical power (e.g., − or N) and may be referred to as negative mirrors or converging mirrors. The convex mirrors may have a positive optical power (e.g., + or P) and may be referred to as positive mirrors or diverging mirrors.

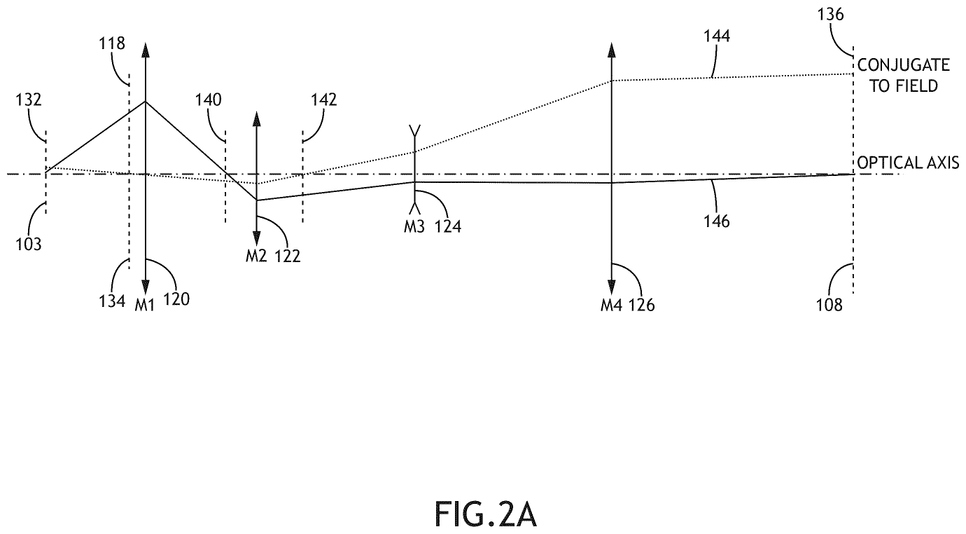

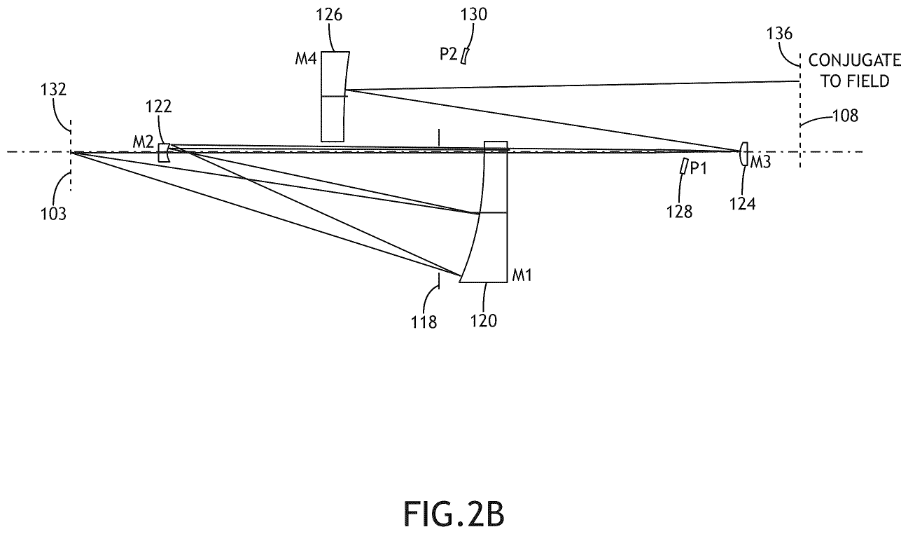

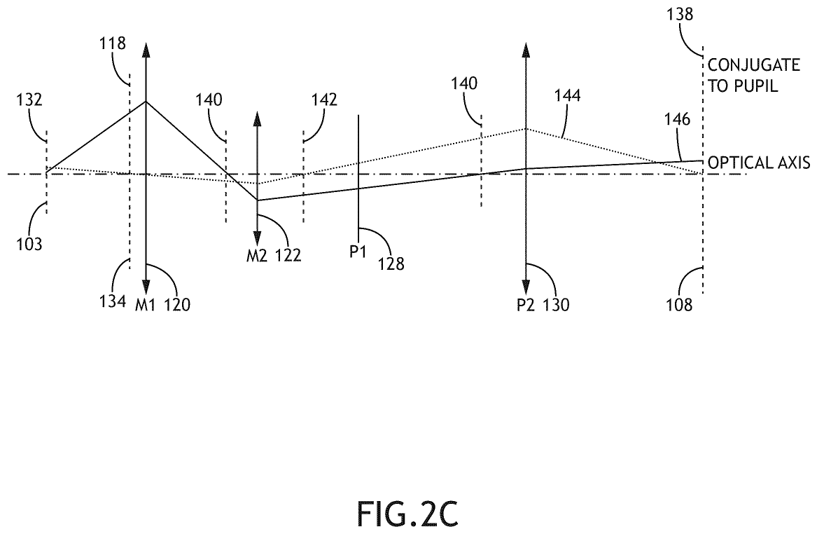

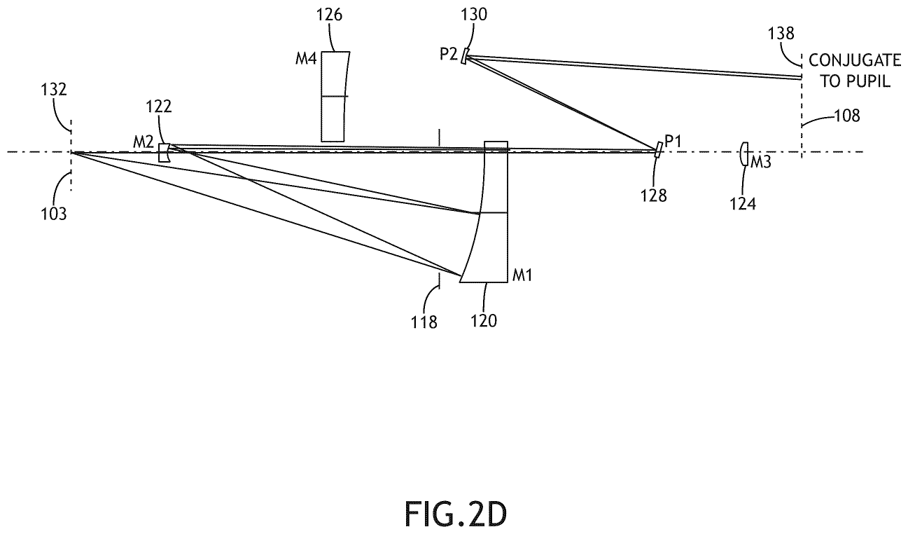

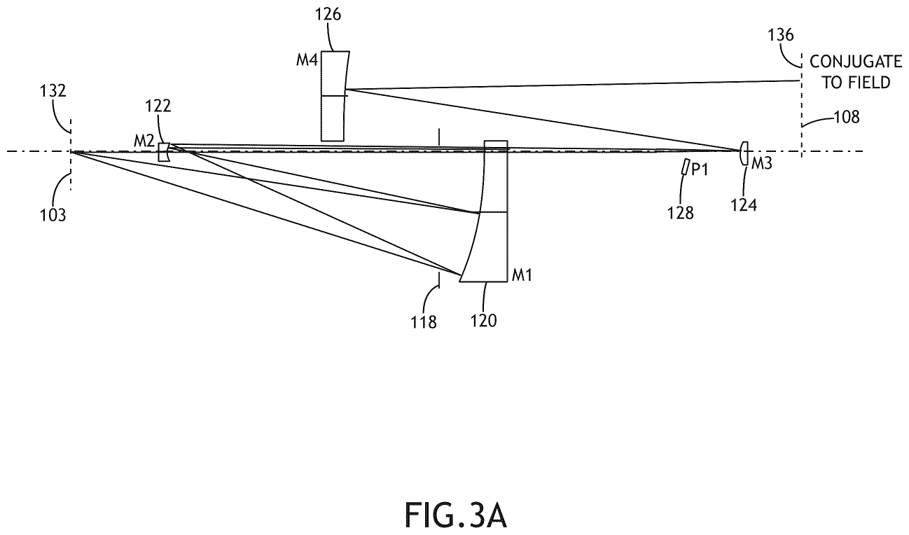

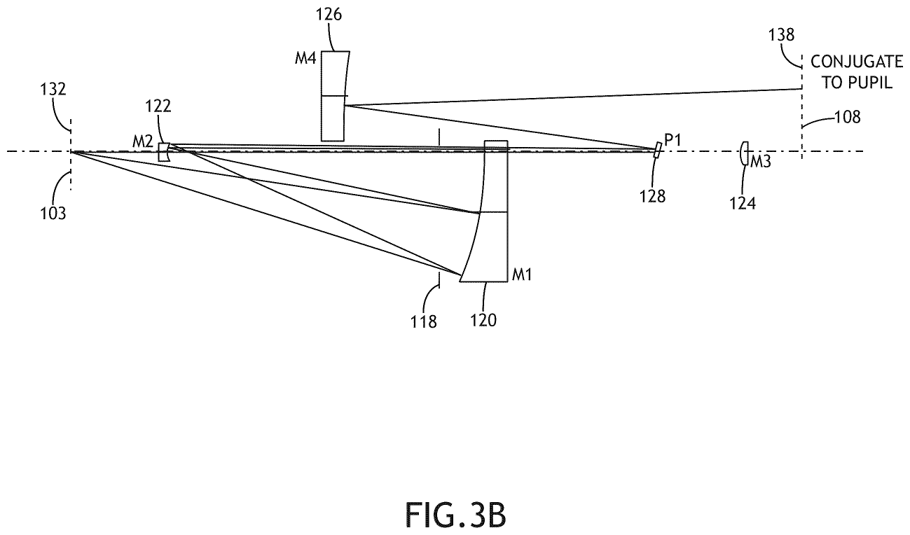

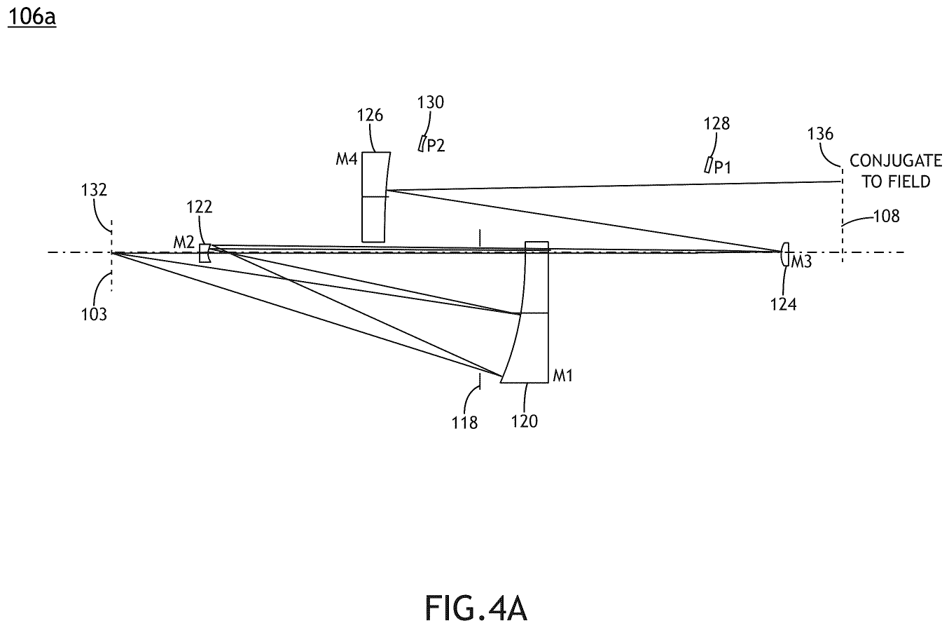

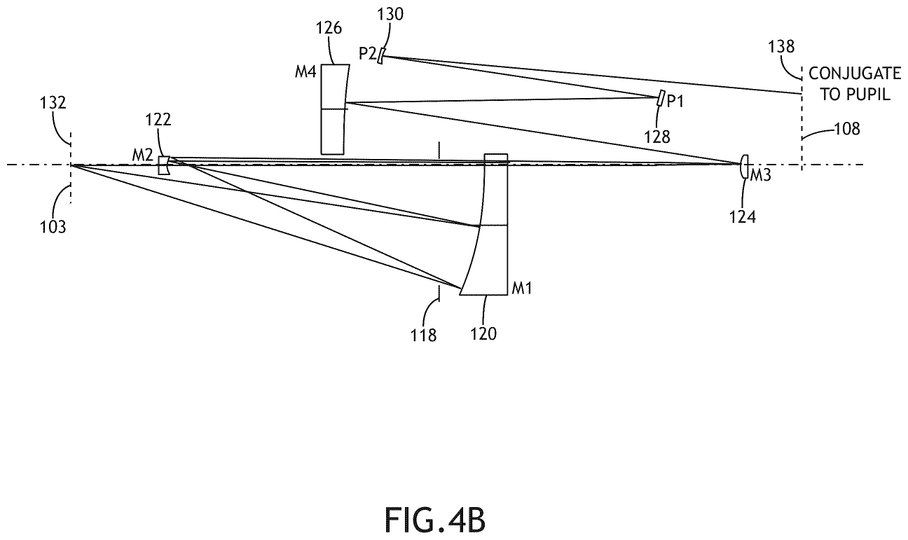

The imaging optics 106 may include an even number of reflections for the collected light 109 in the field-imaging mode 106a and/or pupil-imaging mode 106b. The even number of reflections may be beneficial for maintaining parity of the collected light 109 and/or for spacing the detector 108 away from the stage 110. The imaging optics 106 may include four reflections in the field-imaging mode 106a and may include four reflections or six reflections in the pupil-imaging mode 106b. The imaging optics 106 may include a configuration with six optical mirrors and with four reflections in both the field-imaging mode 106a and the pupil-imaging mode 106b (see FIG. 2A-2D), a configuration with five optical mirrors and with four reflections in both the field-imaging mode 106a and the pupil-imaging mode 106b (see FIG. 3A-3B), and/or a configuration with six optical mirrors, with four reflections in the field-imaging mode 106a, and six reflections in the pupil-imaging mode 106b (see FIG. 4A-4B). The configurations of the imaging optics 106 are described further herein with reference to the subsequent figures. The number of the optical mirrors and the arrangements of the optical powers of the imaging optics 106, may be based on the objective optics 114 and/or the pupil-relay optics 116. The collected light 109 may reflect from either four optical mirrors or six optical mirrors in the imaging optics 106. For example, the collected light 109 may reflect from four optical mirrors in the field-imaging mode 106a. For instance, the collected light 109 may reflect from the first objective mirror 120, the second objective mirror 122, the third objective mirror 124, and the fourth objective mirror 126 in the field-imaging mode 106a (see FIG. 2A-2B, 3A, 4A). By way of another example, the collected light 109 may reflect from either four optical mirrors or six optical mirrors in the pupil-imaging mode 106b. For instance, the collected light 109 may reflect from the first objective mirror 120, the second objective mirror 122, the first pupil-relay mirror 128, and the second pupil-relay mirror 130 in the pupil-imaging mode 106b (see FIG. 2C-2D). By way of another instance, the collected light 109 may reflect from the first objective mirror 120, the second objective mirror 122, the first pupil-relay mirror 128, and the fourth objective mirror 126 in the pupil-imaging mode 106b (see FIG. 3B). By way of another instance, the collected light 109 may reflect from the first objective mirror 120, the second objective mirror 122, the third objective mirror 124, and the fourth objective mirror 126, the first pupil-relay mirror 128, and the second pupil-relay mirror 130 in the pupil-imaging mode 106b (see FIG. 4B).

The objective optics 114 may include an even number of mirrors. For example, the objective optics 114 may include four mirrors. The objective optics 114 may include the first objective mirror 120, the second objective mirror 122, the third objective mirror 124, and the fourth objective mirror 126. The first objective mirror 120, the second objective mirror 122, the third objective mirror 124, and the fourth objective mirror 126 may also be referred to as respective of mirror M1, mirror M2, mirror M3, and mirror M4. Standard nomenclature regarding mirrors is used as to the objective optics 114. For example, the mirror receiving and reflecting the light from the field plane 132 is designated M1, the mirror receiving and reflecting the light from mirror M1 is designated M2, and so forth for the mirror M3, and the mirror M4. The first objective mirror 120, the second objective mirror 122, the third objective mirror 124, and the fourth objective mirror 126 may reflect the collected light 109 in sequence to the detector 108 in the field-imaging mode 106a. The objective optics 114 may be arranged such that the collected light 109 reflects in sequence from the field plane 132 to the first objective mirror 120, the second objective mirror 122, the third objective mirror 124, and the fourth objective mirror 126 before imaging the field images 136 on the detector 108 when the imaging optics 106 are in the field-imaging mode 106a. The first objective mirror 120 may be a first optical mirror of the objective optics 114 after the sample 103. The fourth objective mirror 126 may be a last optical mirror of the objective optics 114 before the detector 108.

The objective optics 114 may optically magnify the field images 136 on the detector 108. In this regard, the objective optics 114 may be an objective. The field images 136 may be imaged on the detector 108 with a select magnification. The optical magnification provided by the objective optics 114 may be at least one-hundred times. For example, the optical magnification may be between 250 and 1000 times. For instance, the optical magnification may between 500 and 1000 times. The field size of the collected light 109 on the detector 108 after magnification by the objective optics 114 may be on the order of tens or hundreds of millimeters. The optical magnification may be selected for critical sampling scaling with the wavelength divided by the numerical aperture to accommodate a size of the patterns on the sample 103. At increasingly smaller technology nodes, the collected light 109 may be magnified increasingly larger, thereby facilitating detection of the patterns.

The first objective mirror 120, the second objective mirror 122, the third objective mirror 124, and the fourth objective mirror 126 may include positive or negative optical powers. For example, the first objective mirror 120 may be concave (−), the second objective mirror 122 may be concave (−), the third objective mirror 124 may be convex (+), and the fourth objective mirror 126 may be concave (−). In this example, the objective optics 114 may be arranged −, −, +, and −. Although the mirrors M1-M4 are described as being, concave, concave, convex, and concave, this is not intended as a limitation of the present disclosure. It is contemplated that the mirrors M1-M4 may be any suitable pattern, such as, but not limited to: concave, convex, concave, and concave (e.g., −, +, −, −); or the like. However, the −, −, +, and-arrangement may be beneficial for providing the optical magnification and the field size of the conjugate to the field plane 132 on the detector 108.

The pupil-relay optics 116 may also be referred to as apodization measurement optics. The pupil-relay optics 116 may include an even number of mirrors. For example, the pupil-relay optics 116 may include two mirrors. For instance, the pupil-relay optics 116 may include the first pupil-relay mirror 128 and/or the second pupil-relay mirror 130. The first pupil-relay mirror 128 and the second pupil-relay mirror 130 may also be referred to as respective of mirror P1 and mirror P2, although this is not intended to be limiting. The first pupil-relay mirror 128 and the second pupil-relay mirror 130 may reflect the collected light 109 in sequence to the detector 108. The pupil-relay optics 116 may be arranged such that the collected light 109 reflects in sequence from the objective optics 114 to the first pupil-relay mirror 128 and the second pupil-relay mirror 130 before imaging the conjugate of the pupil plane 134 on the detector 108 when the imaging optics 106 are in the pupil-imaging mode 106b. The second pupil-relay mirror 130 may be a last optical mirror of the pupil-relay optics 116 before the detector 108. By way of another instance, the pupil-relay optics 116 may include the first pupil-relay mirror 128 and the fourth objective mirror 126.

The first pupil-relay mirror 128 and the second pupil-relay mirror 130 may include a select optical power. For example, the first pupil-relay mirror 128 may be flat (e.g., zero optical power, plano), concave, or convex and the second pupil-relay mirror 130 may be concave (−). For instance, the first pupil-relay mirror 128 may be flat and the second pupil-relay mirror 130 may be concave (−). In this instance, the pupil-relay optics 116 may be arranged 0 and −. The first pupil-relay mirror 128 may have no converging or diverging effect on the collected light 109 where the first pupil-relay mirror 128 is flat.

The third objective mirror 124, the fourth objective mirror 126, and/or the second pupil-relay mirror 130 may be fixed in position and orientation relative to the detector 108. The second objective mirror 122 and/or the first pupil-relay mirror 128 may be moveable relative to the detector 108.

The imaging optics 106 may be configured between the field-imaging mode 106a and the pupil-imaging mode 106b. The imaging optics 106 may be configured between the field-imaging mode 106a and the pupil-imaging mode 106b based on the position of the first pupil-relay mirror 128. The imaging optics 106 may be configured from the field-imaging mode 106a to the pupil-imaging mode 106b by extending the first pupil-relay mirror 128 into the imaging path 107. Similarly, the imaging optics 106 may be configured from the pupil-imaging mode 106b to the field-imaging mode 106a by retracting the first pupil-relay mirror 128 from the imaging path 107. The imaging optics 106 may be configured in the field-imaging mode 106a when the first pupil-relay mirror 128 is retracted out of the imaging path 107 of the collected light 109 and may be configured in the pupil-imaging mode 106b when the first pupil-relay mirror 128 is extended into the imaging path 107 of the collected light 109. The first pupil-relay mirror 128 may be extended and retracted by moving relative to the collected light 109, using one or more actuators (not depicted).

Notably, the imaging optics 106 may not simultaneously image the field images 136 and the pupil images 138 on the detector 108. Rather, the imaging optics 106 may sequentially image the field images 136 and the pupil images 138 on the detector 108. For example, the imaging optics 106 may image the pupil images 138 on the detector 108 during calibration of the inspection system 100. By way of another example, the imaging optics 106 may image the field images 136 on the detector 108 during runtime of the inspection system 100.

The detector 108 may be configured to detect the field images 136 and/or the pupil images 138 from the collected light 109. The detector 108 may be a time-delay-integration detector array. The detector 108 may detect both the field images 136 and the pupil images 138, based on the configuration of the imaging optics 106.

The detector 108 may be configured to provide the field images 136 and/or the pupil images 138 to the controller 112. The controller 112 may receive the field images 136 and/or the pupil images 138 from the detector 108. The controller 112 may use the field images 136 and/or the pupil images 138 to determine a pupil-intensity profile 148, compensate for a relay-reflectivity profile 150, generate a simulated image 152, detect one or more defects on the sample 103, or the like. Advantageously, the pupil-relay optics 116 may enable the detector 108 to detect the pupil images 138 for use by the controller 112.

The controller 112 may determine the pupil-intensity profile 148 from the pupil images 138. The pupil-intensity profile 148 may be a measurement of the intensity profile of the pupil plane 134. The pupil-intensity profile 148 may also be referred to as a pupil apodization or the like.

The pupil images 138 may include the pupil-intensity profile 148 which may be adjusted by the pupil-relay optics 116 based on the relay-reflectivity profile 150 of the pupil-relay optics 116. The relay-reflectivity profile 150 may be a reflectivity profile of the first pupil-relay mirror 128 and/or the second pupil-relay mirror 130. For example, the relay-reflectivity profile 150 may be the reflectivity profile over the length of the first pupil-relay mirror 128 and/or the second pupil-relay mirror 130. The reflectivity profile may also be referred to as a reflectivity nonuniformity. The relay-reflectivity profile 150 may be based on the shape of the pupil-relay optics 116 and/or the incidence angle of the collected light 109 on the pupil-relay optics 116.

The relay-reflectivity profile 150 may provide uncertainty to the measurement of the pupil-intensity profile 148 determined from the pupil images 138. For example, the pupil images 138 may be the pupil-intensity profile 148 multiplied with the relay-reflectivity profile 150, at the corresponding positions at which the collected light 109 defining the pupil-intensity profile 148 reflects from the corresponding position of the pupil-relay optics 116 defining the pupil-intensity profile 148.

The imaging optics 106 may compensate for the relay-reflectivity profile 150 by moving the second objective mirror 122 relative to the collected light 109 when the imaging optics 106 are configured in the pupil-imaging mode 106b. By moving the second objective mirror 122, the beam position of the collected light 109 may move on the first pupil-relay mirror 128, the second pupil-relay mirror 130, and/or the detector 108. In the pupil-imaging mode 106b, the second objective mirror 122 may be moved to shift the beam position on the first pupil-relay mirror 128, the second pupil-relay mirror 130, and/or the detector 108. For example, the second objective mirror 122 may be moved perpendicular (e.g., along an X-axis and a Y-axis) to the optical axis of the collected light 109. The pupil-intensity profile 148 of the collected light 109 may remain the same even as the position of the collected light 109 moves on the first pupil-relay mirror 128, the second pupil-relay mirror 130, and/or the detector 108. The pupil images 138 and the relay-reflectivity profile 150 change dependent on the position of the collected light 109 while the pupil-intensity profile 148 remains the same. Thus, the changes in the pupil images 138 due to the movement may correspond directly to the relay-reflectivity profile 150.

The controller 112 may cause the imaging optics 106 to compensate for the relay-reflectivity profile 150 by moving the second objective mirror 122. The controller 112 may compensate for the relay-reflectivity profile 150 when determining the pupil-intensity profile 148 from the pupil images 138. The controller 112 may compensate for the relay-reflectivity profile 150 when determining the pupil-intensity profile 148 from the pupil images 138 by moving the second objective mirror 122 and detecting changes in the pupil images 138 corresponding to the relay-reflectivity profile 150. The movement of the beam position on the first pupil-relay mirror 128, the second pupil-relay mirror 130, and/or the detector 108 may enable the controller 112 to calibrate the relay-reflectivity profile 150 of the pupil-relay optics 116 by comparing the beam intensity in the pupil images 138 with the different landing positions on the second pupil-relay mirror 130.

After the compensation for the relay-reflectivity profile 150, the pupil-intensity profile 148 may be determined from the pupil images 138. The pupil-relay optics 116 may provide the feasible construction and measurement method to measure the pupil-intensity profile 148 without being affected by the relay-reflectivity profile 150 of the pupil-relay optics 116 via the compensation. The calibration may minimize the impact of the relay-reflectivity profile 150 by the pupil-relay optics 116, which may enable measuring the pupil-intensity profile 148 from the pupil images 138.

The controller 112 may be configured to generate a simulated image 152. The simulated image 152 may also be referred to as a simulated field image, a rendered image, or the like. The simulated image 152 may be a field image that the inspection system 100 is expected to observe of the sample 103 based on the design and the optical properties of the imaging optics 106, the detector 108, the collected light 109, and the like. The controller 112 may generate the simulated image 152 based on the design and/or the optical properties. The design may refer to a design of the sample 103 that is generated by a semiconductor device designer in a design process in advance of printing of the design. The design of the sample 103 may be maintained in a database that describes the intended pattern on the sample. The controller 112 may use the pupil images 138 and/or the pupil-intensity profile 148 to generate the simulated image 152. For example, the controller 112 may generate the simulated image 152 based on the pupil-intensity profile 148 (e.g., to compensate for errors when generating the simulated image 152). Determining the pupil-intensity profile 148 from the pupil images 138 may enable the controller 112 to generate the simulated image 152 from the pupil-intensity profile 148. Thus, the pupil-relay optics 116 may enable generating the simulated image 152 without the use of a beamsplitter in the imaging path 107.

FIGS. 2A-2D illustrate the imaging optics 106, in accordance with one or more embodiments of the present disclosure. The imaging optics 106 may be configured with six optical mirrors and may be configured with four reflections in both the field-imaging mode 106a and the pupil-imaging mode 106b. The first pupil-relay mirror 128 may be extended into and retracted from the imaging path 107 between the second objective mirror 122 and the third objective mirror 124.

The first pupil-relay mirror 128 may be retracted from the imaging path 107 between the second objective mirror 122 and the third objective mirror 124 in the field-imaging mode 106a. In the field-imaging mode 106a, the collected light 109 may not reflect from the pupil-relay optics 116. The collected light 109 may not pass to the first pupil-relay mirror 128 in the field-imaging mode 106a. Instead, the collected light 109 may reflect from the third objective mirror 124 and the fourth objective mirror 126 to the detector 108. The chief rays 144 may be at maximum field height between the fourth objective mirror 126 and the detector 108 in the field-imaging mode 106a.

The first pupil-relay mirror 128 may be extended into the imaging path 107 between the second objective mirror 122 and the third objective mirror 124 in the pupil-imaging mode 106b. In the pupil-imaging mode 106b, the collected light 109 may not reflect from the third objective mirror 124 and/or the fourth objective mirror 126. The collected light 109 may not pass to the third objective mirror 124 in the pupil-imaging mode 106b. The first pupil-relay mirror 128 may intercept the collected light 109, such that the collected light 109 does not reach the third objective mirror 124. The first pupil-relay mirror 128 may reflect the collected light 109 to the second pupil-relay mirror 130 which may reflect the collected light 109 to the detector 108. After the second objective mirror 122, the chief rays 144 may have a diverging angle. In the configuration, the first pupil-relay mirror 128 may be flat and the second pupil-relay mirror 130 may be concave. The first pupil-relay mirror 128 may not converge or diverge the chief rays 144. The second pupil-relay mirror 130 may converge the chief rays 144 on the detector 108.

The intermediate field conjugates 140 may be in the imaging path 107 between the first objective mirror 120 and the second objective mirror 122 in the field-imaging mode 106a and/or the pupil-imaging mode 106b. The intermediate field conjugates 140 may also be in the imaging path 107 between the first pupil-relay mirror 128 and the second pupil-relay mirror 130 in the pupil-imaging mode 106b.

The intermediate pupil conjugates 142 may be in the imaging path 107 between the second objective mirror 122 and the third objective mirror 124 in the field-imaging mode 106a. The intermediate pupil conjugates 142 may also be in the imaging path 107 between the second objective mirror 122 and the first pupil-relay mirror 128 in the pupil-imaging mode 106b.

FIGS. 3A-3B illustrate the imaging optics 106, in accordance with one or more embodiments of the present disclosure. The imaging optics 106 may be configured with five optical mirrors and may be configured with four reflections in both the field-imaging mode 106a and the pupil-imaging mode 106b. Although the pupil-relay optics 116 are described as including the second pupil-relay mirror 130, this is not intended as a limitation of the present disclosure. The fourth objective mirror 126 may perform the function of the second pupil-relay mirror 130. For example, if the detector 108 is sufficiently large, the fourth objective mirror 126 may perform the function of the second pupil-relay mirror 130.

The discussion of the second pupil-relay mirror 130 is incorporated herein by reference in the entirety as to the second pupil-relay mirror 130. The first pupil-relay mirror 128 may be extended into the imaging path 107 between the second objective mirror 122 and the third objective mirror 124 in the pupil-imaging mode 106b. In the pupil-imaging mode 106b, the collected light 109 may not reflect from the third objective mirror 124. The first pupil-relay mirror 128 may intercept the collected light 109, such that the collected light 109 does not reach the third objective mirror 124. The first pupil-relay mirror 128 may reflect the collected light 109 to the fourth objective mirror 126 which may reflect the collected light 109 to the detector 108. The fourth objective mirror 126 may converge the chief rays 144 on the detector 108. In this configuration, the first pupil-relay mirror 128 may be flat, concave, or convex and the fourth objective mirror 126 may be concave. The curvature of the first pupil-relay mirror 128 may be necessary to image the pupil images 138 on the detector 108.

FIGS. 4A-4B illustrate the imaging optics 106, in accordance with one or more embodiments of the present disclosure. The imaging optics 106 may be configured with six optical mirrors, may be configured with four reflections in the field-imaging mode 106a, and may be configured with six reflections in the pupil-imaging mode 106b. The first pupil-relay mirror 128 may be extended into and retracted from the imaging path 107 between the fourth objective mirror 126 and the detector 108.

The first pupil-relay mirror 128 may be retracted from the imaging path 107 between the fourth objective mirror 126 and the detector 108 in the field-imaging mode 106a. The collected light 109 may pass directly from the fourth objective mirror 126 to the detector 108.

The first pupil-relay mirror 128 may be extended into the imaging path 107 between the fourth objective mirror 126 and the detector 108 in the pupil-imaging mode 106b. The collected light 109 may reflect from the fourth objective mirror 126, to the first pupil-relay mirror 128, to the second pupil-relay mirror 130 before imaging the pupil images 138 on the detector 108. In the configuration, the first pupil-relay mirror 128 may be flat and the second pupil-relay mirror 130 may be concave.

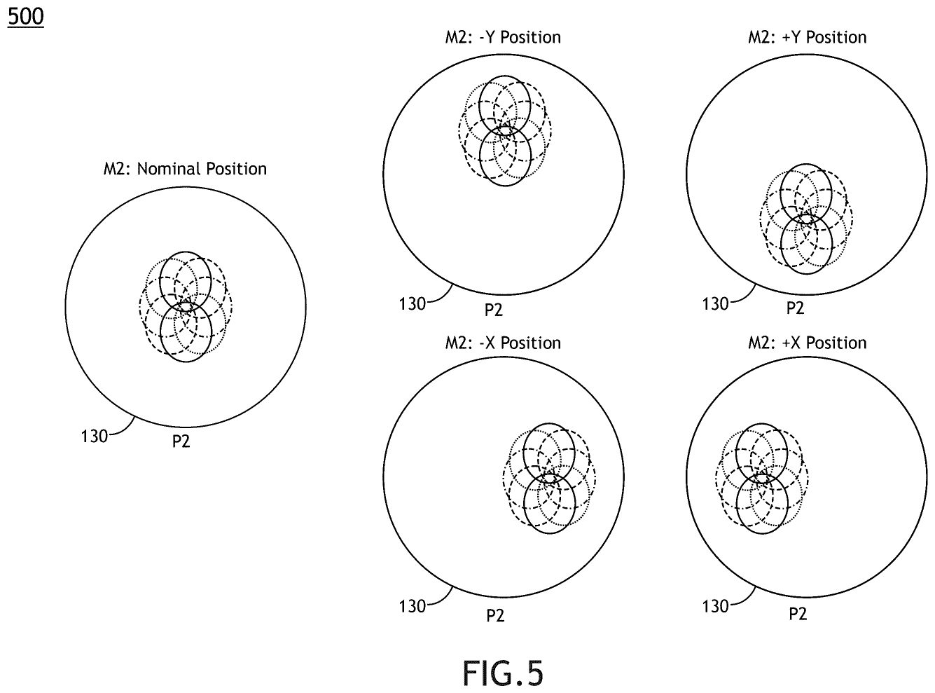

FIG. 5 illustrates a beam footprint diagram 500, in accordance with one or more embodiments of the present disclosure. The beam footprint diagram 500 illustrates the footprint of the collected light 109 on the second pupil-relay mirror 130 (P2) for five different positions of the second objective mirror 122 (M2). In these examples, the second objective mirror 122 is adjusted between a nominal position, a negative Y position, a positive Y position, a negative X position, and a positive X position.

The collected light 109 may fall within a clear aperture of the second pupil-relay mirror 130. For example, the controller 112 may control the beam position via the movement of the second objective mirror 122 such that the collected light 109 does not exceed the edges of the first pupil-relay mirror 128, the second pupil-relay mirror 130, and/or the detector 108.

The collected light 109 is illustrated as eight different ovals from different field points on the sample 103. The position of the field points of the collected light 109 on the second pupil-relay mirror 130 may move based on the movement of the second objective mirror 122. For example, when the second objective mirror 122 is in the nominal position, the field points of the collected light 109 may be arranged in a polar array centered about the center of the second pupil-relay mirror 130. By moving the second objective mirror 122, the beam position may move up/down and/or left/right. The pupil-intensity profile 148 may not change with the movement of the second objective mirror 122. However, the pupil images 138 may change based on the position of the relay-reflectivity profile 150 of the second pupil-relay mirror 130 at which the field points reflect from the second pupil-relay mirror 130. Thus, the movement of the second objective mirror 122 may enable the controller 112 to distinguish between the pupil-intensity profile 148 and the relay-reflectivity profile 150.

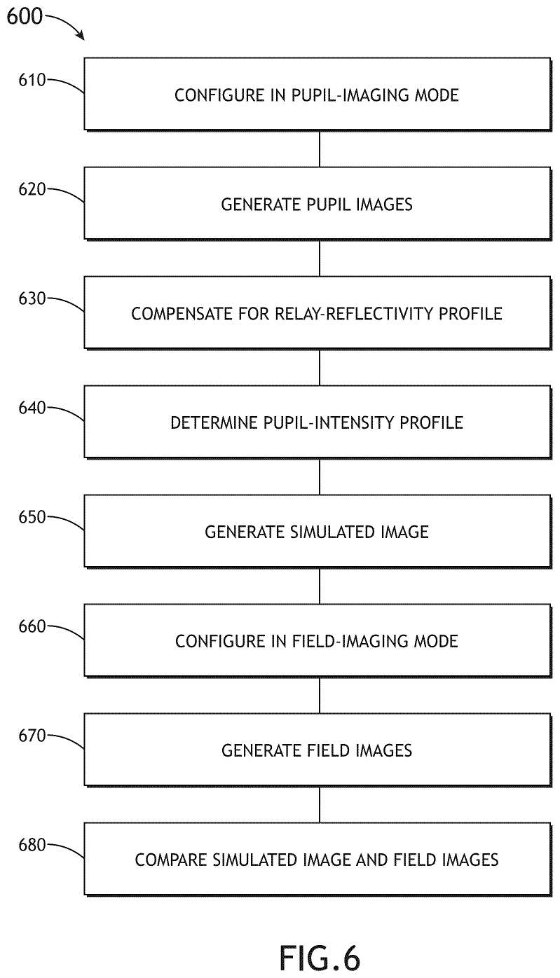

FIG. 6 illustrates a flow diagram of a method 600, in accordance with one or more embodiments of the present disclosure. The embodiments and the enabling technologies described previously herein in the context of the inspection system 100 and the imaging optics 106 should be interpreted to extend to the method. The controller 112 may cause the inspection system 100 and/or the imaging optics 106 to perform one or more steps of the method. The method may be a measurement and/or calibration method using the second objective mirror 122 and/or the pupil-relay optics 116. It is further noted, however, that the method is not limited to the architecture of the inspection system 100 and the imaging optics 106.

In a step 610, imaging optics may be configured in a pupil-imaging mode by extending a first pupil-relay mirror into an imaging path. For example, the imaging optics 106 may be configured in the pupil-imaging mode 106b by extending the first pupil-relay mirror 128 into the imaging path 107. For instance, the first pupil-relay mirror 128 may be extended into the imaging path 107 between the second objective mirror 122 and the third objective mirror 124 or between the fourth objective mirror 126 and the detector 108.

In a step 620, an inspection system may generate pupil images while the imaging optics are configured in the pupil-imaging mode. For example, the inspection system 100 may generate the pupil images 138 while the imaging optics 106 are configured in the pupil-imaging mode 106b. The illumination 101 may be emitted by the illumination source 102. The illumination optics 104 may direct the illumination 101 to the sample 103 and illuminate the sample 103 with the illumination 101. The illumination 101 may reflect from the sample 103 as the collected light 109. The imaging optics 106 may direct the collected light 109 from the sample 103 to the detector 108 along the imaging path 107 and image the pupil images 138 on the detector 108. The detector 108 may detect the pupil images 138 and provide the pupil images 138 to the controller 112.

In a step 630, the imaging optics may compensate for a relay-reflectivity profile by moving a second objective mirror relative to the collected light. For example, the imaging optics 106 may compensate for the relay-reflectivity profile 150 by moving the second objective mirror 122 relative to the collected light 109. The controller 112 may cause the second objective mirror 122 to move relative to the collected light 109 as the pupil images 138 are received (e.g., using a feedback control).

In a step 640, a pupil-intensity profile of the collected light may be determined from the pupil images. For example, the pupil-intensity profile 148 of the collected light 109 may be determined from the pupil images 138. The controller 112 may determine the pupil-intensity profile 148 of the collected light 109 from the pupil images 138 after compensating for the relay-reflectivity profile 150.

In a step 650, a simulated image may be generated based on the pupil-intensity profile. For example, the simulated image 152 may be generated based on the pupil-intensity profile 148.

In a step 660, imaging optics may be configured in a field-imaging mode by retracting the first pupil-relay mirror from the imaging path. For example, the imaging optics 106 may be configured in the field-imaging mode 106a by retracting the first pupil-relay mirror 128 from the imaging path 107.

In a step 670, the inspection system may generate field images while the imaging optics are configured in the field-imaging mode. For example, the inspection system 100 may generate the field images 136 while the imaging optics 106 are configured in the field-imaging mode 106a. The illumination 101 may be emitted by the illumination source 102. The illumination optics 104 may direct the illumination 101 to the sample 103 and illuminate the sample 103 with the illumination 101. The illumination 101 may reflect from the sample 103 as the collected light 109. The imaging optics 106 may direct the collected light 109 from the sample 103 to the detector 108 along the imaging path 107 and image the field images 136 on the detector 108. The detector 108 may detect the field images 136 and provide the field images 136 to the controller 112.

In a step 680, the controller may compare the simulated image and the field images to detect defects on the sample. For example, the controller 112 may compare the simulated image 152 and the field images 136 to detect defects on the sample 103.

Referring generally again to the figures. The inspection system 100 may be an EUV inspection system. For example, the inspection system 100 may be an actinic inspection system by using the in-band EUV light that may represent what will be realized using EUV light during lithography. The inspection system 100 may operate in a vacuum to prevent the atmosphere from absorbing the illumination 101 and/or the collected light 109.

The pupil plane 134 may or may not be the same as an illumination pupil plane of the illumination aperture stop of the illumination optics 104. For example, the pupil plane 134 may be different than the illumination pupil plane of the illumination aperture stop of the illumination optics 104. The illumination pupil plane may be detected by the inspection system 100 using one or more separate methods, which are not described herein, such as, but not limited to, monitoring illumination brightness distribution by imaging the illumination source 102 with a reference pick-up in the illumination path 105 or a separate path.

The second objective mirror 122 may or may not partially obscure the first objective mirror 120 from the collected light 109 coming from the sample 103. For example, the second objective mirror 122 may partially obscure the first objective mirror 120. Part of the area of the first objective mirror 120 may be blocked by the second objective mirror 122 from receiving the collected light 109.

The first objective mirror 120 may include an opening. The collected light 109 may reflect from the second objective mirror 122 and pass through the opening of the first objective mirror 120. The collected light 109 reflecting from the second objective mirror 122 may pass through the opening to the third objective mirror 124 and/or to the first pupil-relay mirror 128. The collected light 109 reflecting from the third objective mirror 124 to the fourth objective mirror 126 may or may not pass back through the opening in the first objective mirror 120.

The imaging path 107 may include one or more components which are not depicted. For example, the imaging path 107 may include a spectral purity filter (not depicted). The spectral purity filter may be between the objective optics 114 and the detector 108. The spectral purity filter may be a bandpass filter for the collected light 109, and configured to pass portions of the EUV wavelengths (e.g., in-band EUV light), stop DUV wavelengths or above, and/or stop X-ray wavelengths or below.

The mirrors and/or optics which are configured to reflect the EUV light (e.g., the in-band EUV light) may be any suitable material. For example, the material which reflects the in-band EUV light having the wavelength of 13.5 nm may be ruthenium (Ru), molybdenum (Mo) (e.g., Mo/Si multilayer mirrors), niobium (Nb), engineered high density carbon films having high Sp3 content (e.g. tetrahedral (Ta-C)), or the like. The material may also be a multi-layer coating. Mirrors for EUV light may be coated with multi-layer coating to reach adequate reflectivity. The mirrors may include a select reflectivity. For example, the mirrors may include a reflectivity between 60 and 70%. The range of incidence angles on any of the mirrors may be selected within the limits of multilayer deposition process technology. The incidence angles may be a grazing incidence angles relative to the collected light 109. For example, the grazing incidence angles may be between 0 and 20 degrees. For instance, the incidence angles of the first pupil-relay mirror 128 and/or the second pupil-relay mirror 130 to the collected light 109 in the pupil-imaging mode 106b may be between 0 and 20 degrees (e.g., between 10 and 20 degrees). In embodiments, the incidence angles of the first pupil-relay mirror 128 and/or the second pupil-relay mirror 130 to the collected light 109 in the pupil-imaging mode 106b may be between 10 and 15 degrees. Decreasing the grazing incidence angles may be desirable to reduce a power loss associated with the reflection of the collected light 109 from the imaging optics 106. As the incidence angle of the pupil-relay optics 116 increases, the reflectivity dependence on angle and/or wavelength may also become more sensitive, such that smaller incidence angles may be desirable. However, the incidence angle may also be selected to enable imaging the field images 136 and/or the pupil images 138 on the detector 108 within the allowable geometry of the imaging optics 106.

The concave mirrors and/or the convex mirrors may be spherical mirrors and/or aspherical mirrors. For example, the first objective mirror 120 may be an aspherical mirror. By way of another example, the second objective mirror 122, the third objective mirror 124, the fourth objective mirror 126, and/or the second pupil-relay mirror 130 may be spherical.

The movement of the second objective mirror 122 may not adjust the beam position on the second objective mirror 122. For example, even if the second objective mirror 122 moves, the beam footprint on the first objective mirror 120 and/or the second objective mirror 122 does not change because of the optical configuration of the objective optics 114. In this regard, the reflectivity profile of the first objective mirror 120 and the second objective mirror 122 are deterministic when determining the pupil-intensity profile 148 and/or such that the pupil-relay optics 116 may be extended into the imaging path 107 between the second objective mirror 122 and the third objective mirror 124.

The controller 112 may move the second objective mirror 122 a select number of times when compensating for the relay-reflectivity profile 150. The number of times may be increased to increase the accuracy at which the pupil-intensity profile 148 and/or the relay-reflectivity profile 150 are detected. The number of times may also be based on how accurately the detector 108 may detect the pupil images 138. For example, if the detector 108 may measure a very small change between the pupil images 138, a small number of beam shifts may be sufficient. Alternatively, if the detector 108 has a low sensitivity or if the change in the relay-reflectivity profile 150 is small, many beam shifts may be required.

Since the detector 108 is used to detect both the field images 136 and the pupil images 138, the pupil-relay optics 116 may be configured with the position of the first pupil-relay mirror 128 and the second pupil-relay mirror 130 together with the concavity of the second pupil-relay mirror 130 to enable imaging the pupil images 138 on the detector 108 with or without adjusting the design of the objective optics 114.

The controller 112 may be configured to control the motion of the stage 110, the second objective mirror 122, and/or the first pupil-relay mirror 128. For example, the controller 112 may be configured to drive one or more actuators (e.g., the stage 110 actuator, the second objective mirror 122 actuator, or the first pupil-relay mirror 128 actuator) of the inspection system 100. The controller 112 may configure the imaging optics 106 between the field-imaging mode 106a and the pupil-imaging mode 106b by moving the first pupil-relay mirror 128. The controller 112 may also be configured to determine the pupil-intensity profile 148 from the pupil images 138 by moving the second objective mirror 122 relative to the collected light 109.

The detector 108 may detect the field images 136 and the pupil images 138 in a first and second scan. The detector 108 may detect the field images 136 and/or the pupil images 138 of the sample 103 as the illumination 101 is scanned over the sample 103. As the illumination 101 is scanned over the sample 103, the charges are shifted from pixel-to-pixel. The charges may be read-out as lines of the field images 136 and/or the pupil images 138. By synchronizing the charge shift rate with the velocity of the scanning, the detector 108 may integrate a signal intensity at a fixed position on the detector 108 to detect the field images 136 and/or the pupil images 138. The total integration time may be regulated by changing the velocity of the scanning and providing more/less pixels in the direction of the scanning. The charges may be read-out in a line orthogonal to the scanning direction. The line may form sequential lines of the field images 136 and/or the pupil images 138.

The inspection system 100 may be configured to perform swathing. Swathing may refer to using the detector 108 to collect a horizontally long image from one side to the other of the sample. Many horizontal swaths may be combined to cover the sample 103 from side-to-side and top-to-bottom.

It is contemplated that the configuration with the four reflective mirrors in the pupil-imaging mode 106b may be more beneficial than the configuration with six reflective mirrors in the pupil-imaging mode 106b. For example, the configuration with the four reflective mirrors in the pupil-imaging mode 106b may be beneficial to provide adequate inspection performance at minimum mirror count, enabling the use of low brightness plasma-based EUV sources. Extending the first pupil-relay mirror 128 into the imaging path 107 after the fourth objective mirror 126 may significantly reduce the brightness of the pupil images 138 on the detector 108, as compared to extending into the imaging path 107 after the second objective mirror 122. After multiple reflections from near-normal incidence mirrors in imaging optics in an EUV system, transmission of the collected light 109 may fall below 1%. Extending the first pupil-relay mirror 128 into the imaging path 107 between the second objective mirror 122 and the third objective mirror 124 may prevent the light from reflecting from the third objective mirror 124 and the fourth objective mirror 126, thereby reducing the brightness loss. Therefore, the configuration with the four reflective mirrors may be more desirable than the configuration with the six reflective mirrors. However, it is contemplated that the configuration depicted may be possible with sufficient brightness of the illumination 101.

The objective optics 114 and/or the pupil-relay optics 116 may optically magnify the pupil images 138 on the detector 108. The pupil images 138 may be less magnified than the field images 136. For example, the pupil images 138 may be about 1/20^{th} the size of the field images 136, although this is not intended to be limiting.

The measurement of the relay-reflectivity profile 150 may be performed during the installation phase of the inspection system 100 as one of the calibration procedures, and applied to “Die to Database” mode inspection afterward. According to the needs, the measurement of the relay-reflectivity profile 150 may be repeated using the pupil-relay optics 116 during the runtime.

Generating the simulated image 152 may include one or more steps. The controller 112 may be configured to performing the one or more steps by executing a generative model. The generative model may perform image rendering with a deep learning technique, or the like. For example, the generative model may model from design (polygons) with estimated near field and an accurate or approximate optical system model. By way of another example, the generative model may model from a stack of geometry and material information to calculate or estimate the near field and to learn and use an accurate or approximate optical system model.

The field images 136 and the simulated image 152 may be compared for one or more purposes such as, but not limited to, defect detection, alignment, compensation, or the like. The controller 112 may perform a die-to-database inspection using the field images 136 to detect defects in the sample 103. For example, the controller 112 may use the field images 136 and the simulated image 152 for the recognition and categorization of the defect, using a “die-to-database” mode. The controller 112 may compare the field images 136 with the simulated image 152 to perform the die-to-database inspection and detect the defects. The controller 112 may compare the field images 136 with the simulated image 152 using any suitable process, such as by subtraction, a deep learning technique, or the like.

The controller 112 may subtract the field images 136 from the simulated image 152 to generate a difference image, and detect defects in the sample 103 using the difference image. The difference image may remove patterns which are supposed to be on the sample 103, leaving only the defects in the difference image. The difference operation may remove the pattern of the sample 103, leaving the defect as a perturbation of a quasi-uniform background signal. The controller 112 may detect defects using a difference image by applying one or more defect detection algorithms and/or methods to the difference image. For example, signals in the difference image may be compared to a threshold, and of the signals that are above the threshold may be identified as defects or potential defects, while any of the signals that are below the threshold may not be identified as defects or potential defects. Of course, many other defect detection algorithms and methods are known in the art, and the embodiments described herein are not limited to any one defect detection algorithm or method. In other words, the results of the comparison described herein may be input to any suitable defect detection algorithm and/or method known in the art.

The controller 112 may compare the field images 136 and the simulated image 152 with a deep learning (DL) technique, or the like, to detect defects in the sample 103. For instance, the controller 112 may compare parameters extracted from the field images 136 and the simulated image 152. The controller 112 may also be configured to characterize the one or more defects (e.g. brightfield or darkfield defect, spatial property of defect, or the like) which are detected.

Inaccuracies in the simulated image 152 may lead to inaccuracies in the identification of the defects in the reticle when comparing the simulated image 152 with the field images 136. Thus, the pupil-intensity profile 148 for the relay-reflectivity profile 150 may be beneficial to improve the accuracy of the relay-reflectivity profile 150 and/or the ability to detect defects in the field images 136.

Although the pupil images 138 and/or the pupil-intensity profile 148 are described as being used to generate the simulated image 152, this is not intended as a limitation of the present disclosure. It is contemplated that the pupil images 138 and/or the pupil-intensity profile 148 may be beneficial for various purposes within the inspection system 100.

In the field-imaging mode 106a, the second objective mirror 122 may be moved to minimize the wavefront error of the field images 136. For example, the second objective mirror 122 may minimize the wavefront error caused by the objective optics 114.

A controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

A controller may include one or more processors and/or memory. The memory may maintain program instructions which may be executable by the processors, causing the controller to perform any of the various functions of the controller.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive, and the like. The memory medium may include flash memory cells, or other type memory, discrete EPROM or EEPROM, or the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet, and the like).

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B. ” It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. Imaging optics comprising:
an aperture stop, wherein the aperture stop defines a pupil plane of collected light in an imaging path, wherein the pupil plane is a reciprocal plane to a field plane on a sample, wherein the aperture stop is arranged in the imaging path between the sample and objective optics;
the objective optics, wherein the objective optics comprise a first objective mirror, a second objective mirror, a third objective mirror, and a fourth objective mirror; and
pupil-relay optics, wherein the pupil-relay optics comprise at least a first pupil-relay mirror, wherein the imaging optics are configurable between a field-imaging mode and a pupil-imaging mode, wherein the imaging optics are configured in the pupil-imaging mode by extending the first pupil-relay mirror into the imaging path and are configured in the field-imaging mode by retracting the first pupil-relay mirror from the imaging path, wherein the objective optics are configured to image field images on a detector in the field-imaging mode, wherein the field images are a conjugate of the field plane, wherein at least the first objective mirror and the second objective mirror of the objective optics and the pupil-relay optics are configured to image pupil images on the detector in the pupil-imaging mode, wherein the pupil images are a conjugate of the pupil plane.

2. The imaging optics of claim 1, wherein the collected light comprises at least one of vacuum ultraviolet light or soft X-ray light.

3. The imaging optics of claim 2, wherein the collected light comprises the vacuum ultraviolet light; wherein the vacuum ultraviolet light comprises at least one of far ultraviolet light or extreme ultraviolet light.

4. The imaging optics of claim 3, wherein the vacuum ultraviolet light comprises the extreme ultraviolet light; wherein the extreme ultraviolet light has a wavelength of between 10 nm and 121 nm.

5. The imaging optics of claim 1, wherein the objective optics and the pupil-relay optics are catoptric.

6. The imaging optics of claim 1, wherein the imaging optics comprises an even number of reflections for the collected light in the field-imaging mode and the pupil-imaging mode, wherein the imaging optics comprise four reflections in the field-imaging mode and either four reflections or six reflections in the pupil-imaging mode.

7. The imaging optics of claim 6, wherein the imaging optics comprise the four reflections in the pupil-imaging mode, wherein the first pupil-relay mirror is extended into and retracted from the imaging path between the second objective mirror and the third objective mirror.

8. The imaging optics of claim 7, wherein the pupil-relay optics comprise a second pupil-relay mirror, wherein the collected light is configured to reflect from the first objective mirror, the second objective mirror, the first pupil-relay mirror, and the second pupil-relay mirror in the pupil-imaging mode.

9. The imaging optics of claim 8, wherein the imaging optics comprise an intermediate field conjugate in the imaging path between the first objective mirror and the second objective mirror in the field-imaging mode and the pupil-imaging mode, wherein the imaging optics comprise an additional intermediate field conjugate between the first pupil-relay mirror and the second pupil-relay mirror in the pupil-imaging mode, wherein the imaging optics comprise an intermediate pupil conjugate in the imaging path between the second objective mirror and the third objective mirror in the field-imaging mode, wherein the intermediate pupil conjugate is between the second objective mirror and the first pupil-relay mirror in the pupil-imaging mode.

10. The imaging optics of claim 7, wherein the collected light is configured to reflect from the first objective mirror, the second objective mirror, the first pupil-relay mirror, and the fourth objective mirror in the pupil-imaging mode.

11. The imaging optics of claim 6, wherein the imaging optics comprise the six reflections in the pupil-imaging mode, wherein the first pupil-relay mirror is extended into and retracted from the imaging path between the fourth objective mirror and the detector, wherein the pupil-relay optics comprise a second pupil-relay mirror, wherein the collected light is configured to reflect from the first objective mirror, the second objective mirror, the third objective mirror, and the fourth objective mirror, the first pupil-relay mirror, and the second pupil-relay mirror in the pupil-imaging mode.

12. The imaging optics of claim 1, wherein the first objective mirror is concave, the second objective mirror is concave, the third objective mirror is convex, and the fourth objective mirror is concave.

13. The imaging optics of claim 1, wherein the pupil-relay optics comprise a second pupil-relay mirror, wherein the third objective mirror, the fourth objective mirror, and the second pupil-relay mirror are fixed in position and orientation relative to the detector.

14. The imaging optics of claim 1, wherein the pupil-relay optics comprise a second pupil-relay mirror, wherein the first pupil-relay mirror is one of flat, concave, or convex, wherein the second pupil-relay mirror is concave.

15. The imaging optics of claim 14, wherein the first pupil-relay mirror is flat.

16. The imaging optics of claim 1, wherein an incidence angle of the first pupil-relay mirror to the collected light in the pupil-imaging mode is between 0 and 20 degrees.

17. The imaging optics of claim 16, wherein the incidence angle is between 10 and 20 degrees.

18. The imaging optics of claim 1, wherein the imaging optics do not simultaneously image the field images and the pupil images on the detector.

19. The imaging optics of claim 1, wherein the pupil images comprise a pupil-intensity profile which is adjusted based on a relay-reflectivity profile of the pupil-relay optics.

20. The imaging optics of claim 19, wherein the imaging optics are configured to compensate for the relay-reflectivity profile by moving the second objective mirror relative to the collected light.

21. An inspection system comprising:
imaging optics comprising:
an aperture stop, wherein the aperture stop defines a pupil plane of collected light in an imaging path, wherein the pupil plane is a reciprocal plane to a field plane on a sample, wherein the aperture stop is arranged in the imaging path between the sample and objective optics;
the objective optics, wherein the objective optics comprise a first objective mirror, a second objective mirror, a third objective mirror, and a fourth objective mirror; and
pupil-relay optics, wherein the pupil-relay optics comprise at least a first pupil-relay mirror, wherein the imaging optics are configurable between a field-imaging mode and a pupil-imaging mode, wherein the imaging optics are configured in the pupil-imaging mode by extending the first pupil-relay mirror into the imaging path and are configured in the field-imaging mode by retracting the first pupil-relay mirror from the imaging path, wherein the objective optics are configured to image field images on a detector in the field-imaging mode, wherein the field images are a conjugate of the field plane, wherein at least the first objective mirror and the second objective mirror of the objective optics and the pupil-relay optics are configured to image pupil images on the detector in the pupil-imaging mode, wherein the pupil images are a conjugate of the pupil plane;
an illumination source;
illumination optics;
a stage, wherein the stage is configured to support the sample;
the detector; and
a controller, wherein the controller is configured to receive the field images and the pupil images from the detector.

22. The inspection system of claim 21, wherein the pupil images comprise a pupil-intensity profile which is adjusted based on a relay-reflectivity profile of the pupil-relay optics, wherein the imaging optics are configured to compensate for the relay-reflectivity profile by moving the second objective mirror relative to the collected light, wherein the controller is configured to cause the second objective mirror to move relative to the collected light.

23. The inspection system of claim 22, wherein the controller is configured to determine the pupil-intensity profile from the pupil images.

24. The inspection system of claim 23, wherein the controller is configured to:
extend the first pupil-relay mirror into the imaging path to configure the imaging optics in the pupil-imaging mode;
receive the pupil images while the imaging optics are configured in the pupil-imaging mode;
compensate for the relay-reflectivity profile by moving the second objective mirror relative to the collected light;
determine the pupil-intensity profile of the collected light from the pupil images after compensating for the relay-reflectivity profile;
generate a simulated image based on the pupil-intensity profile;
retract the first pupil-relay mirror from the imaging path to configure the imaging optics in the field-imaging mode;
receive the field images while the imaging optics are configured in the field-imaging mode; and
compare the simulated image and the field images.

25. A method comprising:
extending a first pupil-relay mirror of pupil-relay optics of imaging optics into an imaging path to configure the imaging optics in a pupil-imaging mode;
detecting pupil images while the imaging optics are configured in the pupil-imaging mode;
compensating for a relay-reflectivity profile by moving a second objective mirror of objective optics of the imaging optics relative to a collected light;
determining a pupil-intensity profile of the collected light from the pupil images after compensating for the relay-reflectivity profile;
generating a simulated image based on the pupil-intensity profile;
retracting the first pupil-relay mirror from the imaging path to configure the imaging optics in a field-imaging mode;
detecting field images while the imaging optics are configured in the field-imaging mode; and
comparing the simulated image and the field images.
